(19) United States
(12) Patent Application Publication
(10) Pub. No.: US 2011/0234297 A1
(43) Pub. Date: Sep. 29, 2011

(54) SEMICONDUCTOR INTEGRATED CIRCUIT AND ITS CONTROL TECHNIQUE

(75) Inventors: Tetsuya FUKUOKA, Hamura (JP); Yasuhiro Fujimura, Hamura (JP); Masanao Yamaoka, White Plains, NY (US)

(73) Assignee: HITACHI, LTD.

(21) Appl. No.: 13/026,241

(22) Filed: Feb. 12, 2011

(30) Foreign Application Priority Data
Mar. 29, 2010 (JP) JP2010-074764

(51) Int. Cl. H03K 17/687

(52) U.S. Cl. 327/427

(57) ABSTRACT

Provided is a control technique of a semiconductor integrated circuit capable by which power on/shut-off of a power shut-off area at an optimum speed in accordance with variations in fabricating devices as suppressing the malfunction of a circuit during operation in the power on/shut-off. A semiconductor integrated circuit includes: an always-on area; a power shut-off area; and a plurality of power-supply switches connected to the power shut-off area for supplying or shutting off the power to the power shut-off area.

Further, the semiconductor integrated circuit includes a switch controller for carrying out the power on/shut-off by controlling on/off of the plurality of power-supply switches and changing the transition time of the power on/shut-off in accordance with a performance of each of the semiconductor integrated circuit after fabricating. Further, the semiconductor integrated circuit includes a memory for recording the performance of each of the semiconductor integrated circuit after fabricating.

### CROSS-REFERENCE TO RELATED APPLICATION

The present application claims priority from Japanese Patent Application No. 2010-074764 filed on Mar. 29, 2010, the content of which is hereby incorporated by reference into this application.

### TECHNICAL FIELD OF THE INVENTION

The present invention relates to a control technique for a semiconductor integrated circuit. More particularly, the present invention relates to a technique effectively applied to a control method for a power on/shut-off switch used in a power on/shut-off technique.

### BACKGROUND

Along with fast speed and high integration for a large-scale integrated circuit (LSI) in recent years, increase in power consumption of the LSI has been a problem. Further, in a microfabrication process, along with increase in a leakage current of a transistor, increase in DC power has been significant. On the other hand, in plural-function integrated LSI such as a system-on-chip (SOC), it is not required to operate all circuits on the LSI during operation of a certain functional block, and a block whose operation is unnecessary exists.

Conventionally, to such a stoppable block, a clock gating technique of stopping to supply a clock and reducing AC power has been applied. In recent years, a power on/shut-off technique of shutting off to supply the power and reducing DC power has been further applied.

For example, Japanese Patent Application Laid-Open Publication No. 2008-218722 (Patent Document 1) and US Patent No. 2009/0102287 (Patent Document 2) describe a control method of a power on/shut-off switch used in a power on/shut-off technique.

### SUMMARY

The inventors of the present application have studied on the power on/shut-off technique prior to the present application.

FIG. 2 illustrates a schematic diagram of a circuit system with a power on/shut-off mechanism. The circuit system with the power on/shut-off mechanism includes a power-supply switch SW for power on/shut-off for each operation area in addition to an always-on area 10 and a power shut-off area 20. When logical operation is unnecessary, the power-supply switch SW is turned off to shut off the supply of power, so that the leakage current is shut off and the DC power is reduced.

In such a circuit system with the power on/shut-off mechanism for each area, it is required to shut off and turn on the power of the power shut-off area while other operation areas are continuously operated. FIG. 3 illustrates a power-supply voltage and a power-supply current obtained when the power of the power shut-off area of the circuit system with the power on/shut-off mechanism is shut off. Also, FIG. 4 illustrates the power-supply voltage and the power-supply current obtained immediately after the power-supply switch of the power shut-off area is turned on. In FIGS. 3 and 4, it is assumed that a power-supply current “Idd” is supplied to the always-on area at a power-supply voltage “Vdd” obtained when the power of the power shut-off area is shut off. When the power-supply switch of the power shut-off area is turned on, power supply cannot follow the change of the load immediately after the power-supply switch is turned on, and the power-supply current Idd is continuously supplied without change. A part (a charge/discharge current “'charge”, a leakage current “Ileak”) of the power-supply current Idd flows into the power shut-off area, and therefore, the power shut-off area is charged, and the power-supply voltage of the power shut-off area is increased.

On the other hand, the currents (an alternating current “Iac′”, a direct current “Idc′”) for driving the always-on area are reduced, and therefore, the power-supply voltage of the always-on area is reduced (Vdd′<Vdd), and a magnitude corresponding to the reduction in the power-supply voltage becomes power-supply noise. A magnitude of the power-supply noise depends on the number of the switches in the power shut-off area which are turned on and off simultaneously. When the power-supply noise is generated, a device speed in the always-on area is lowered, and a circuit may malfunction. In order to continuously operate the always-on area, it is required to suppress the power-supply noise affecting the always-on area.

The time required for the power on/shut-off (power on/shut-off time) can be expressed as “the number of total switches turned on and off sequentially until power on/shut-off (the number of total switches SW) divided by the number of switches turned on and off simultaneously or the number of switches per unit time (the number of switch SW turned on and off simultaneously)”.

The power on/shut-off time depends on (1) the leakage current of the power shut-off area and (2) the device speed of the always-on area, and is proportional to (1) and inversely proportional to (2).

That is, when the leakage current of the power shut-off area is small, a necessary charge/discharge amount on the power shut-off area is small, and therefore, the number of total switch SW can be small. On the other hand, when the device speed of the always-on area is fast, an allowed power-supply noise is high, and therefore, the number of switches SW turned on and off simultaneously can be large. As a result, the power on/shut-off time is shortened.

FIG. 5 illustrates power on/shut-off sequences, which can be employed in accordance with device variation in each device on which the circuit system with the power on/shut-off mechanism is mounted, and a relation among the power on/shut-off times of the sequences. Generally, the device speed and the leakage current are varied in accordance with variations in fabricating devices, and there is a relation that the leakage current is large when the device speed is fast and that the leakage current is small when the device speed is slow.

Therefore, the number of switches SW turned on and off simultaneously can be large when the device speed is fast and the leakage current is large (#1 in FIG. 5), and the number of total switches SW can be small when the device speed is slow and the leakage current is small (#2 in FIG. 5), and therefore, the power on/shut-off sequence time can be shortened.

However, the device variations are unknown while designing, and therefore, the devices are designed under the worst condition in the device speed and the leakage current. In this case, the number of total switches SW is large and the number of switches SW turned on and off simultaneously is small (#3 in FIG. 5), and therefore, there arises a problem that the power on/shut-off time becomes long.

FIG. 6 illustrates an example of the worst condition. In this example, the number of total switches SW is 6 when the case of the large leakage current is assumed, and the number of switches SW turned on and off simultaneously is 2 when the case of the slow device speed, and therefore, the power on/shut-off time becomes 3.

In the circuit system with such a power on/shut-off mechanism, for example, Patent Document 1 and Patent Document 2 disclose the technique aiming at suppressing the power-supply noise affecting the always-on area and shortening the power on/shut-off time.

Patent Document 1 discloses a system of controlling a control timing for a power-supply switch in accordance with an inrush current value by providing an inrush current monitor in a power shut-off area.

Generally, in a device having the large leakage current, the device speed is fast. In that case, the power shut-off target area is large, and the inrush current is large, and therefore, the malfunction is not caused even when the power-supply noise is large.

In the system of monitoring only the inrush current as the system disclosed in Patent Document 1, the device speed cannot be taken into consideration, and the control timing for the power-supply switch is set so as not to cause the malfunction even when the device speed is slow, and therefore, the power on/shut-off time becomes adversely long.

Patent Document 2 discloses a system of controlling a power-supply switch in a power shut-off area so as not to exceed an allowed value of a power-supply noise by observing power-supply voltages of the power shut-off area and an always-on area and evaluating an achievement potential of the power shut-off area and the power-supply noise of a peripheral area.

Also in this case, when the device speed is fast, the malfunction is not caused even when the power-supply noise is large. However, in the system of monitoring only the power-supply noise as the system disclosed in Patent Document 2, the device speed cannot be taken into consideration, and the switch control is set so as not to cause the malfunction even when the device speed is slow, and therefore, the power on/shut-off time becomes adversely long.

Accordingly, the present invention solves such problems, and a typical preferred aim of the present invention is to provide a control technique of a semiconductor integrated circuit by which, as suppressing the malfunction in the circuit during operation in power on/shut-off, the power on/shut-off of the power shut-off area at an optimum speed can be achieved in accordance with the variations in fabricating devices.

The above and other preferred aims and novel characteristics of the present invention will be apparent from the description of the present specification and the accompanying drawings.

A summary of the typical ones of the inventions disclosed in the present application will be briefly described as follows.

That is, the summary of the typical one is to include: an always-on area; a power shut-off area; and a plurality of power-supply switches connected to the power shut-off area and supplying or shutting-off the power to the power shut-off area.

Further, it is to include a switch controller for carrying out power on/shut-off by controlling on/off of the plurality of power-supply switches and changing transition time of the power on/shut-off in accordance with a performance of each of the semiconductor integrated circuit after fabricating.

More specifically, in a semiconductor integrated circuit having a circuit system with a mechanism capable of power on/shut-off for each area, in order to carry out the power on/shut-off by changing a power on/shut-off sequence in accordance with a performance of each circuit after fabricating on which the circuit system is mounted, the semiconductor integrated circuit includes: a switch controller for gradually turning on/off the power-supply switches in the power shut-off area in accordance with predetermined time; and a memory capable of recording device information of the circuit after fabricating on which the present circuit system is mounted. After fabrication of the present circuit, device fabrication variation information such as the device speed and leakage current of each circuit are recorded in the memory.

And, in carrying out the power on/shut-off, the switch controller reads variation information in fabricating the device from the memory, sets the number of total switches in accordance with an amount of the leakage current on the power shut-off area, sets the number of switches SW turned on and off simultaneously in accordance with the device speed on the always-on area, and executes the power on/shut-off sequence in an optimum speed in accordance with the device, so that the power on/shut-off is carried out. The effects obtained by typical aspects of the present invention will be briefly described below.

(1) As suppressing the malfunction of the circuit during operation in the power on/shut-off, the power on/shut-off of the power shut-off area at the optimum speed can be achieved in accordance with the variations in fabricating the device.

(2) In the circuit system in which the power on/shut-off time is determined while designing and is fixed afterward, the power on/shut-off time can be set to be shorter than a value designed under the worst condition.

### BRIEF DESCRIPTIONS OF THE DRAWINGS

FIG. 1 is a schematic diagram explaining a circuit system with a power on/shut-off mechanism in accordance with variations in fabricating devices in a semiconductor integrated circuit according to an embodiment of the present invention;

FIG. 2 is a schematic diagram explaining a circuit system with a power on/shut-off mechanism in a conventional semiconductor integrated circuit;

FIG. 3 is a diagram explaining a power-supply voltage and a power-supply current obtained when power of a power shut-off area is shut off in the conventional semiconductor integrated circuit;

FIG. 4 is a diagram explaining the power-supply voltage and power-supply current obtained immediately after a power-supply switch of the power shut-off area is turned on in the conventional semiconductor integrated circuit;

FIG. 5 is a table explaining power on/shut-off time in accordance with device variations in the conventional semiconductor integrated circuit;

FIG. 6 is a diagram explaining a circuit operation and power on/shut-off time of a power on/shut-off control system designed under the worst condition in the conventional semiconductor integrated circuit;

FIG. 7 is a diagram explaining a performing flow of the power on/shut-off control system in accordance with the variations in fabricating the devices in the semiconductor integrated circuit according to the embodiment of the present invention;

FIG. 8 is a diagram explaining the circuit operation and the power on/shut-off time in a case in which a device leakage current is large and a device speed is fast in the power on/shut-off control system in accordance with the variations in fabricating the devices in the semiconductor integrated circuit according to the embodiment of the present invention;

FIG. 9 is a diagram explaining the circuit operation and the power on/shut-off time in a case in which the device leakage current is small and the device speed is slow in the power on/shut-off control system in accordance with the variations in fabricating the devices in the semiconductor integrated circuit according to the embodiment of the present invention;

FIG. 10 is a schematic diagram explaining a power on/shut-off control system of controlling a switch controller and a power-supply switch by outputting information of the variations in fabricating the devices and changing a switch control sequence by an off-chip switch controller in the semiconductor integrated circuit according to the embodiment of the present invention; and

FIG. 11 is a schematic diagram explaining a power on/shut-off control system of controlling the power-supply switch by the off -chip switch controller by outputting information of the variations in fabricating the devices in the semiconductor integrated circuit according to the embodiment of the present invention.

### DETAILED DESCRIPTION OF THE EXEMPLARY EMBODIMENTS

Hereinafter, embodiments of the present invention will be described in detail with reference to the accompanying drawings.

However, the present invention is not limited to the illustrated mode. Note that components having the same function are denoted by the same reference symbols throughout the drawings for describing the embodiment, and the repetitive description thereof will be omitted.

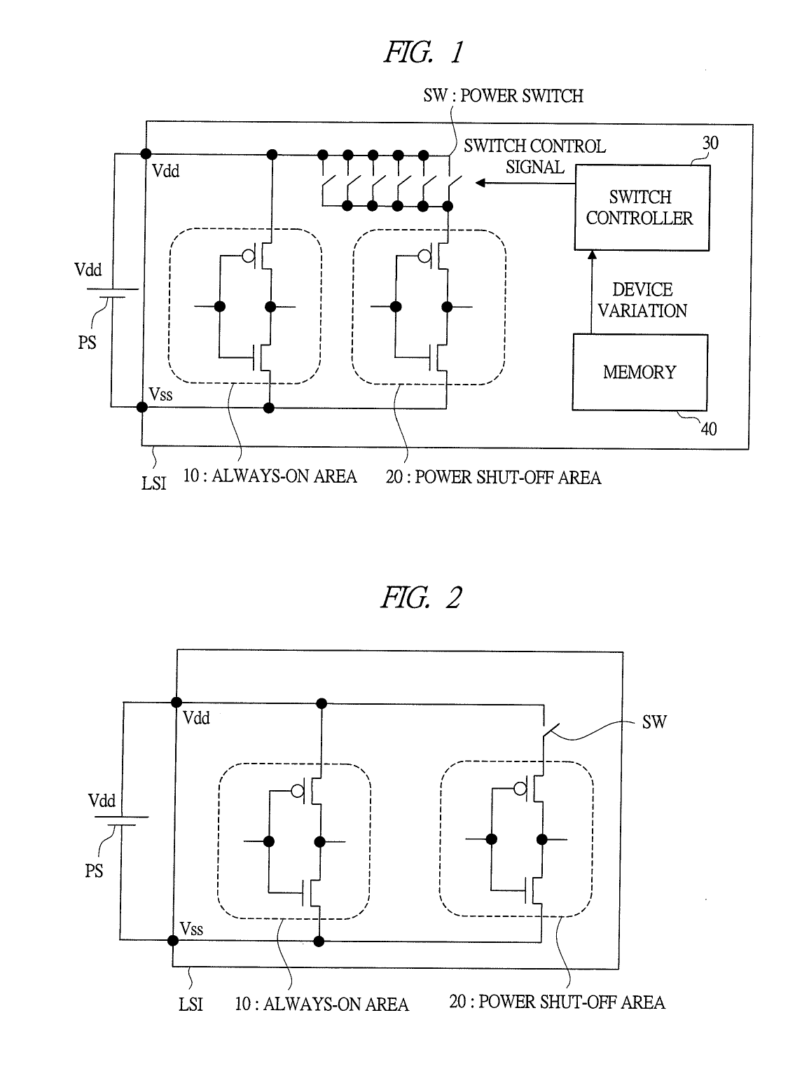

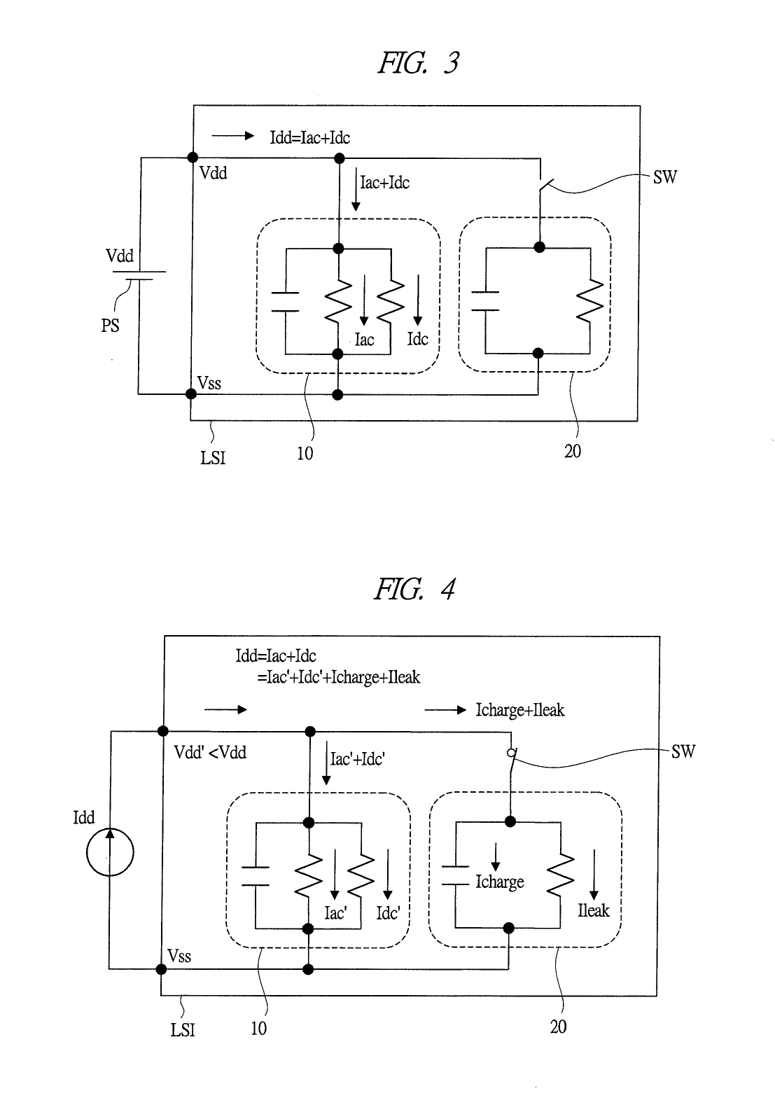

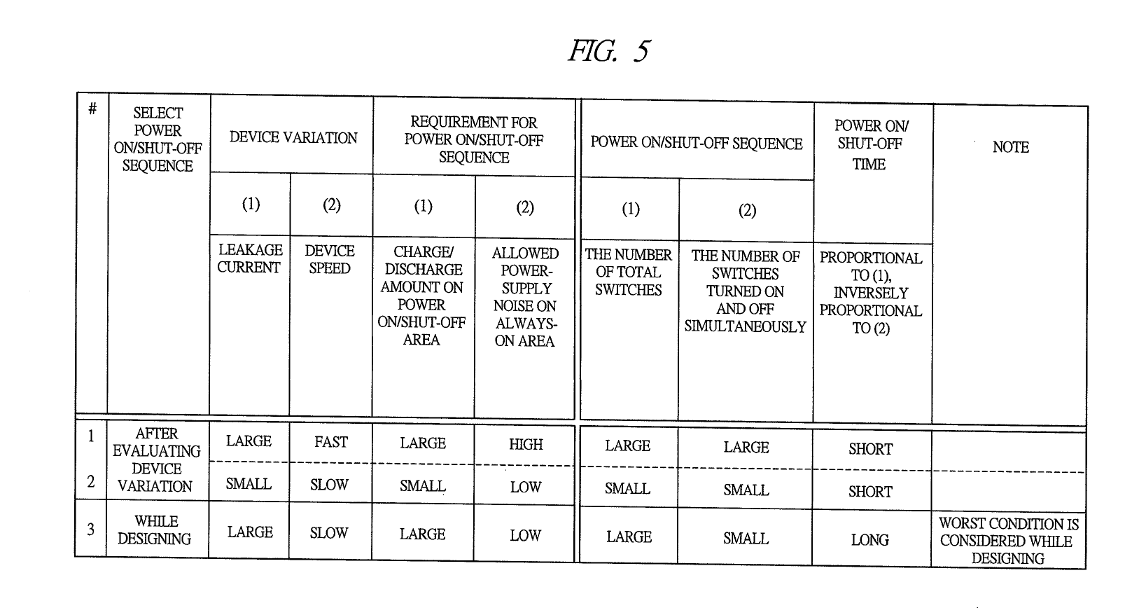

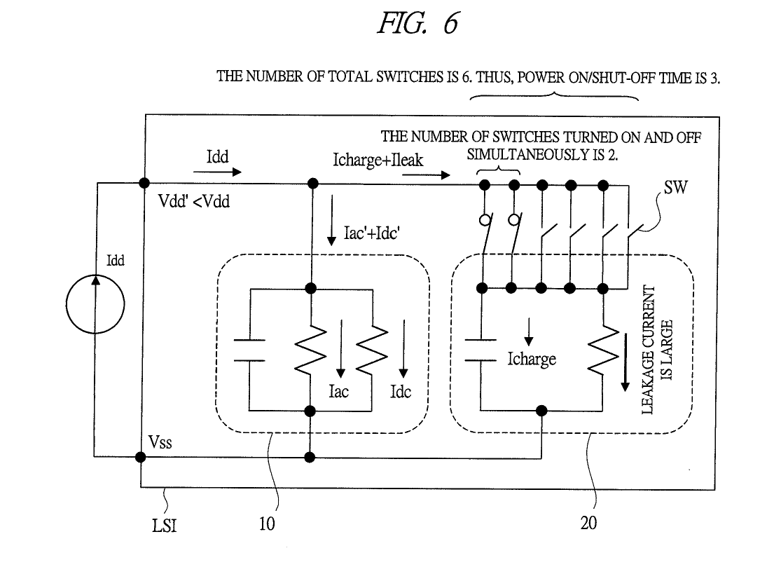

First, a configuration example of a semiconductor integrated circuit according to an embodiment of the present invention will be explained. FIG. 1 is a schematic diagram explaining a circuit system with a power on/shut-off mechanism in accordance with variations in fabricating devices in the semiconductor integrated circuit according to the present embodiment.

In a large-scale integrated circuit LSI of the semiconductor integrated circuit according to the present embodiment, an always-on area 10, which is always operated, and a power shut-off area 20, in which the power supply can be shut off to reduce DC power, are formed. Outside the large-scale integrated circuit LSI, a power supply PS (whose voltage is Vdd) is connected between a terminal of a power-supply voltage (Vdd) and a terminal of a ground voltage (Vss).

Inside the large-scale integrated circuit LSI, the always-on area 10 is connected between the power-supply voltage (Vdd) and the ground voltage (Vss). One side of the power shut-off area 20 is connected to the power-supply voltage (Vdd) via a plurality (six pieces in the example of FIG. 1) of power-supply switches SW for shutting off the power supplied to the power shut-off area 20, and the other side thereof is directly connected to the ground voltage (Vss).

Further, inside the large-scale integrated circuit LSI, in addition to the plurality of power-supply switches SW for supplying or shutting off the power to the power shut-off area 20, the large-scale integrated circuit LSI includes: a switch controller 30 for carrying out the power on/shut-off by controlling on/off of the plurality of power-supply switches SW and changing the transition time of the power on/shut-off in accordance with the performance of each semiconductor integrated circuit after fabricating; and a memory 40 for recording device information including the performance of each semiconductor integrated circuit after fabricating and recording one or a plurality of power on/shut-off sequences.

In the semiconductor integrated circuit as configured above, the switch controller 30 reads the device information from the memory 40 and sets the power on/shut-off sequence in accordance with the device information. In the present embodiment, the number of total switches (the number of total switches SW) is set in accordance with the device leakage current so as to supply the necessary charge/discharge amount for the power shut-off area 20, and the number of switches turned on and off simultaneously (the number of switches SW turned on and off simultaneously) is set in accordance with the device speed so as to suppress the power-supply noise affecting the always-on area. The set number is issued to the plurality of power-supply switches SW as a switch control signal to control the on/off of the power-supply switches SW.

The memory 40 records the information of the variations in fabricating the devices which are different in each semiconductor integrated circuit on which the present circuit system is mounted, such as the device leakage current and the device speed. The memory 40 is composed of a memory element such as a fuse.

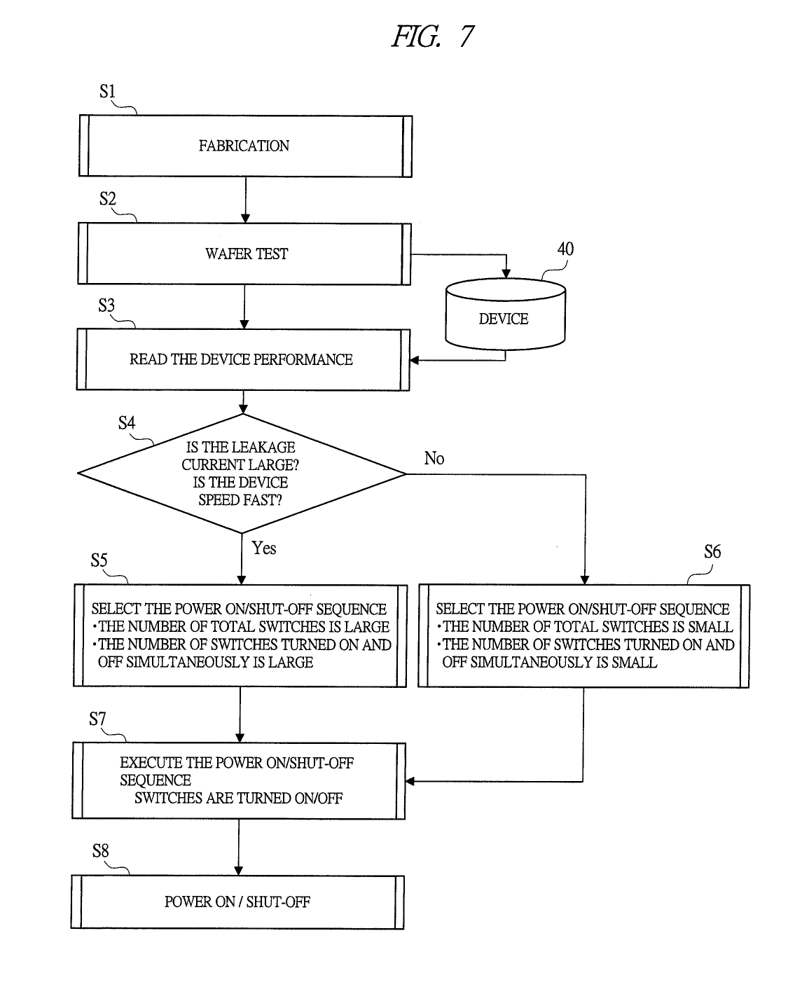

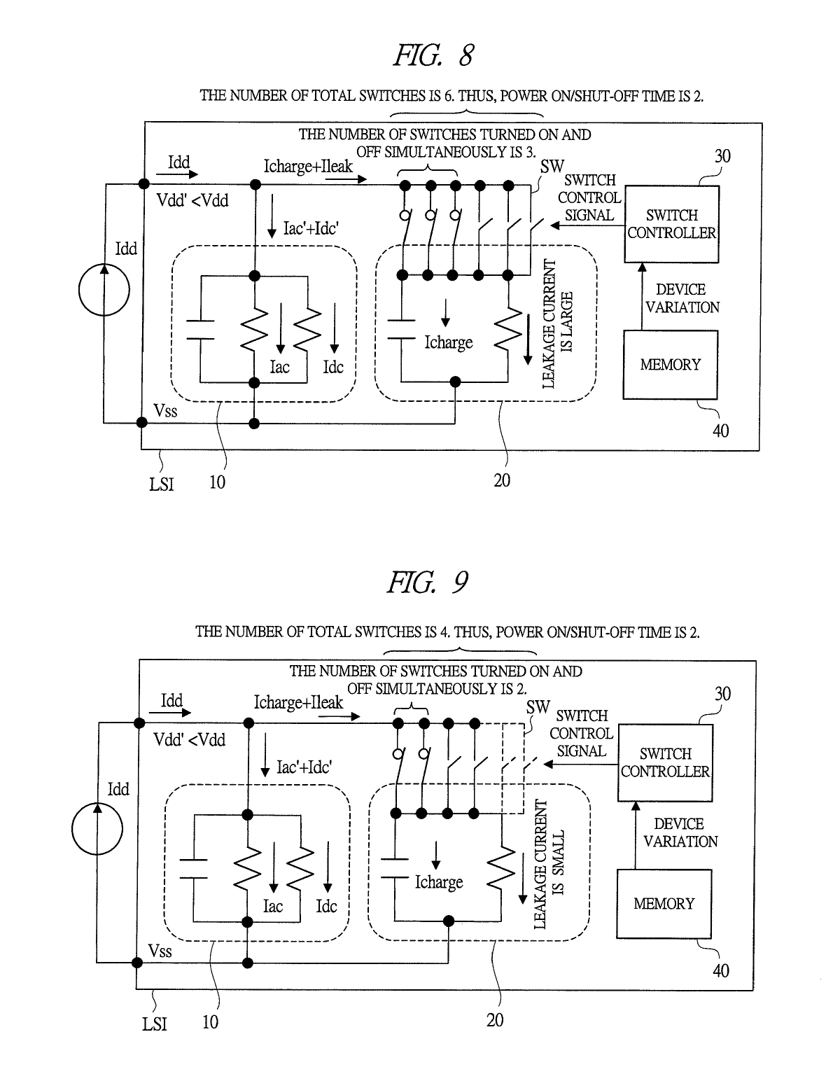

Subsequently, an example of a method of controlling the semiconductor integrated circuit according to the present embodiment will be explained. FIG. 7 is a diagram explaining a performing flow of the power on/shut-off control system in accordance with the variations in fabricating the devices. FIG. 8 is a diagram explaining the circuit operation and the power on/shut-off time in a case in which the device leakage current is large and the device speed is fast in the control method of FIG. 7. FIG. 9 is a diagram explaining the circuit operation and the power on/shut-off time in a case in which the device leakage current is small and the device speed is slow in the control method of FIG. 7.

The semiconductor integrated circuit on which the present circuit system is mounted is fabricated (S1). And then, the information of the variations in fabricating the devices (the leakage current value and the device speed) is recorded in the memory 40 for each semiconductor integrated circuit in a wafer test (S2).

The semiconductor integrated circuit is shipped and used. When the power on/shut-off is executed, the switch controller 30 reads the information of the variations in fabricating the devices from the memory 40 (S3).

Next, the switch controller 30 sets the power on/shut-off sequence in accordance with the device information. At this time, it is determined whether the device leakage current is large or not and whether the device speed is fast or not (S4). When the leakage current is large and the device speed is fast (in a case of “Yes”), the number of total switches SW and the number of the switches SW turned on and off simultaneously are set to be large (S5). FIG. 8 illustrates an example in which the number of total switches SW is set to 6 as same as that designed under the worst condition, and the number of switches SW turned on and off simultaneously is set to 3 as larger than that designed under the worst condition, and therefore, the power on/shut-off time is 2.

Also, in the determination of S4, when the leakage current is small and the device speed is slow (in a case of “No”), the number of total switches SW and the number of switches SW turned on and off simultaneously SW are set to be small (S6). FIG. 9 illustrates an example in which the number of total switches SW is set to 4 as smaller than that designed under the worst condition, and the number of switches SW turned on and off simultaneously is set to 2 as same as that designed under the worst condition, and therefore, the power on/shut-off time is 2.

The set values are issued to the power-supply switch SW as the switch control signal to execute the power on/shut-off sequence.

The power-supply switch SW is turned on/off in accordance with the switch control signal (S7).

When the power on/shut-off sequence is finished, the power of the power shut-off area 20 is turned-on/shut-off (S8).

As described above, by setting the power on/shut-off sequence in accordance with the information of the variations in fabricating the devices, the power on/shut-off of the power shut-off area 20 at the optimum speed can be achieved in accordance with the variations in fabricating the devices as suppressing the malfunction of the circuit during operation.

Also, in the circuit system in which the power on/shut-off time is determined while designing and is fixed afterward, as illustrated in FIGS. 8 and 9, by setting both of the number of total switches SW and the number of switches SW turned on and off simultaneously to be large or small in accordance with the information of the variations in fabricating the devices with a state that the power on/shut-off time is constant, the power on/shut-off time can be set to be shorter than the value designed under the worst condition.

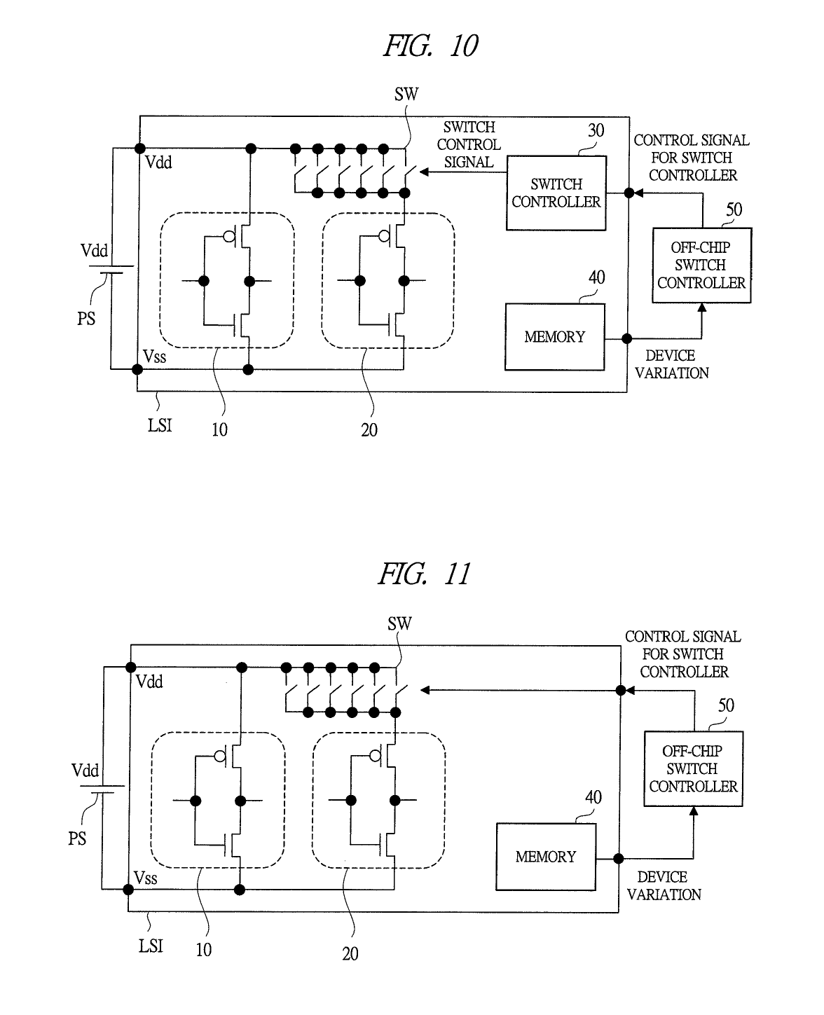

Subsequently, another configuration example of the semiconductor integrated circuit according to the embodiment will be explained. FIG. 10 is a schematic diagram explaining a power on/shut-off control system of controlling the switch controller and the power-supply switch by outputting the information of the variations in fabricating the devices and changing the switch control sequence by an off-chip switch controller. FIG. 11 is a schematic diagram explaining a power on/shut-off control system of controlling the power-supply switch by the off-chip switch controller by outputting the information of the variations in fabricating the devices.

In a large-scale integrated circuit LSI of a semiconductor integrated circuit illustrated in FIG. 10, an off-chip switch controller 50 outside the semiconductor integrated circuit reads the device information recorded in the memory 40. The off-chip switch controller 50 controls the switch controller 30 in accordance with the read device information. The switch controller 30 issues the switch control signal to the power-supply switch SW in accordance with the control from the off-chip switch controller 50 to control the on/off of the power-supply switch SW.

In a large-scale integrated circuit LSI of a semiconductor integrated circuit illustrated in FIG. 11, an off-chip switch controller 50 outside the semiconductor integrated circuit reads the device information recorded in the memory 40. The off-chip switch controller 50 issues the switch control signal to the power-supply switch SW in accordance with the read device information to control the on/off of the power-supply switch SW.

By the configuration examples illustrated in FIGS. 10 and 11, the power on/shut-off time can be set in accordance with the device information by the outside of the semiconductor integrated circuit.

In the foregoing, the invention made by the inventors of the present invention has been concretely described based on the embodiments. However, it is needless to say that the present invention is not limited to the foregoing embodiments and various modifications and alterations can be made within the scope of the present invention.

The control technique for the semiconductor integrated circuit according to the present invention can be used in the control method for the power shut-off switch used in the power on/shut-off technique.

What is claimed is:

1. A semiconductor integrated circuit comprising: an always-on area; a power shut-off area; and a plurality of power-supply switches connected to the power shut-off area for supplying or shutting-off power to the power shut-off area, wherein
the semiconductor integrated circuit includes:
a switch controller for carrying out power on/shut-off by controlling on/off of the plurality of power-supply switches and changing transition time of the power on/shut-off in accordance with a performance of each of the semiconductor integrated circuit after fabricating.

2. The semiconductor integrated circuit according to claim 1, wherein
the switch controller changes a power on/shut-off sequence by changing the number of total switches turned on and off sequentially until the power on/shut-off.

3. The semiconductor integrated circuit according to claim 1, wherein
the switch controller changes a power on/shut-off sequence by changing the number of switches turned on and off simultaneously.

4. The semiconductor integrated circuit according to claim 1, wherein
the switch controller changes a power on/shut-off sequence by changing both of the number of total switches turned on and off sequentially until the power on/shut-off and the number of switches turned on and off simultaneously.

5. The semiconductor integrated circuit according to claim 1, wherein
the switch controller changes a power on/shut-off sequence in accordance with a device leakage current as the performance of each of the semiconductor integrated circuit.

6. The semiconductor integrated circuit according to claim 5, wherein
the switch controller selects a sequence in which the number of total switches turned on and off sequentially until the power on/shut-off is large when the device leakage current is large, and selects a sequence in which the number of total switches turned on and off sequentially until the power on/shut-off is small when the device leakage current is small.

7. The semiconductor integrated circuit according to claim 1, wherein
the switch controller changes a power on/shut-off sequence in accordance with a device speed as the performance of each of the semiconductor integrated circuit.

8. The semiconductor integrated circuit according to claim 7, wherein
the switch controller selects a sequence in which the number of switches turned on and off simultaneously is large when the device speed is fast, and selects a sequence in which the number of switches turned on and off simultaneously is small when the device speed is slow.

9. The semiconductor integrated circuit according to claim 1, wherein
the switch controller changes a power on/shut-off sequence in accordance with a device leakage current and a device speed as the performance of each of the semiconductor integrated circuit.

10. The semiconductor integrated circuit according to claim 9, wherein
the switch controller selects a sequence in which both of the number of total switches turned on and off sequentially until the power on/shut-off and the number of switches turned on and off simultaneously are large when the device leakage current is large and the device speed is fast or when either one of them, and selects a sequence in which both of the number of total switches turned on and off sequentially until the power on/shut-off and the number of switches turned on and off simultaneously are small when the device leakage current is small and the device speed is slow or when either one of them.

11. The semiconductor integrated circuit according to claim 1, wherein
the semiconductor integrated circuit further includes:
a memory for recording the performance of each of the semiconductor integrated circuit after fabricating.

12. The semiconductor integrated circuit according to claim 11, wherein
one or a plurality of power on/shut-off sequences are recorded in the memory.

13. A control method for a semiconductor integrated circuit comprising: an always-on area; a power shut-off area; and a plurality of power-supply switches connected to the power shut-off area for supplying or shutting-off power to the power shut-off area, wherein
the power on/shut-off is carried out by controlling on/off of the plurality of power-supply switches and changing transition time of the power on/shut-off in accordance with the performance of each of the semiconductor integrated circuit after fabricating.

14. The control method for the semiconductor integrated circuit according to claim 13, wherein
a power on/shut-off sequence is changed by changing the number of total switches turned on and off sequentially until the power on/shut-off.

15. The control method for the semiconductor integrated circuit according to claim 13, wherein
a power on/shut-off sequence is changed by changing the number of switches turned on and off simultaneously.

16. The control method for the semiconductor integrated circuit according to claim 13, wherein
a power on/shut-off sequence is changed by changing both of the number of total switches turned on and off sequentially until the power on/shut-off and the number of switches turned on and off simultaneously.

17. The control method for the semiconductor integrated circuit according to claim 13, wherein
a power on/shut-off sequence is changed in accordance with a device leakage current as the performance of each of the semiconductor integrated circuit.

18. The control method for the semiconductor integrated circuit according to claim 17, wherein
a sequence in which the number of total switches turned on and off sequentially until the power on/shut-off is large is selected when the device leakage current is large, and a sequence in which the number of total switches turned on and off sequentially until the power on/shut-off is small is selected when the device leakage current is small.

19. The control method for the semiconductor integrated circuit according to claim 13, wherein
a power on/shut-off sequence is changed in accordance with a device speed as the performance of each of the semiconductor integrated circuit.

20. The control method for the semiconductor integrated circuit according to claim 19, wherein
a sequence in which the number of switches turned on and off simultaneously is large is selected when the device speed is fast, and a sequence in which the number of switches turned on and off simultaneously is small is selected when the device speed is slow.
